(19) United States
(12) Patent Application Publication
(10) Pub. No.: US 2024/0373729 A1
(43) Pub. Date: Nov. 7, 2024

(54) TRANSPARENT DISPLAY PANEL AND DISPLAY DEVICE

(71) Applicant: LG Display Co., Ltd., Seoul (KR)

(72) Inventors: JongHyun PARK, Paju-si (KR); SangMoo SONG, Paju-si (KR)

(73) Assignee: LG Display Co., Ltd., Seoul (KR)

(21) Appl. No.: 18/652,616

(22) Filed: May 1, 2024

(30) Foreign Application Priority Data
May 2, 2023 (KR) 10-2023-0057048

(51) Int. Cl. H10K 59/80; H10K 59/38

(52) U.S. Cl. CPC H10K 59/879; H10K 59/38

(57) ABSTRACT

A transparent display device for improving clarity, visibility, and readability of a display device by reducing haze is discussed. The transparent display device includes a display area having a transmissive area and a non-transmissive area, a plurality of emission areas provided in the non-transmissive area, and a plurality of first optical pattern disposed in each of the plurality of emission areas.

### CROSS-REFERENCE TO RELATED APPLICATIONS

This application claims priority to Korean Patent Application No. 10-2023-0057048 filed in the Republic of Korea on May 2, 2023, the entire contents of which are hereby expressly incorporated by reference into the present application.

### BACKGROUND

### Technical Field

The present disclosure relates to a transparent display panel and a display device including the same. More detail, the present disclosure relates to a transparent display panel and a display device including the same, which are capable of improving transparency while minimizing diffraction phenomenon by external light source and increasing extraction efficiency of internal light.

### Discussion of the Related Art

With advancement in information-oriented societies, demands for display devices that display an image have increased in various forms. Various types of display devices such as a liquid crystal display (LCD) device, a plasma display panel (PDP) device, a Quantum dot Light Emitting Display (QLED), and an organic light emitting display (OLED) device have been widely utilized.

In particular, organic light emitting display devices are attracting attention as next-generation display devices because they are advantageous in terms of power consumption due to low-voltage operation, and also have excellent color reproduction, response speed, viewing angle, and contrast ratio.

In recent years, there has been active research on display devices that have a transmissive area to allow external light to pass through, so that a background located behind the display device or objects or images located on the rear surface of the display device can be viewed.

### BRIEF SUMMARY OF THE DISCLOSURE

The present disclosure is directed to providing a transparent display panel and a display device including that same, which substantially obviate one or more problems due to limitations and disadvantages of the related art.

An aspect of the present disclosure is directed to providing a transparent display panel and a display device including that same, which can minimize diffraction phenomenon of light and reduce haze to improve clarity, visibility, and readability of the display device.

An another aspect of the present disclosure is directed to providing a transparent display panel and a display device including the same, which are capable of improving the extraction efficiency of the emitted light when displaying an image by light emitted from the display device and improving the transmittance.

Another aspect of the present disclosure is directed to providing a transparent display panel and a display device including the same, which are capable of realizing ESG (Environment/Social/Governance) by increasing the lifespan of display devices and reducing the generation of greenhouse gases due to the manufacturing process for producing a new display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display device including a display area including a transmissive area and a non-transmissive area, a plurality of emission areas disposed in the non-transmissive area, and a plurality of first optical patterns disposed in each of the plurality of emission areas.

In another aspect of the present disclosure, there is provided a transparent display panel further including a plurality of second optical patterns disposed at the border of the transmissive area.

The plurality of second optical patterns can be disposed in a zigzag arrangement or irregular arrangement at the border of the transmissive area and at least partly overlap the transmissive area.

The border of the transmissive area can have an embossed pattern or a concavo-convex pattern.

In another aspect of the present disclosure, there is provided a display device including a transparent display panel having a transmissive area and a non-transmissive area in a display area of a first substrate and a second substrate facing each other and a tempered glass disposed on the transparent display panel, wherein a plurality of emission areas and a first optical pattern disposed on the plurality of emission areas are disposed in the non-transmissive area, and a plurality of second optical patterns are disposed between the transmissive area and the non-transmissive area.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 illustrates a display device according to one or more embodiments of the present disclosure;

FIG. 2 is an example of a circuit diagram of a sub-pixel illustrated in FIG. 1;

FIG. 3 is a plan view illustrating a plurality of pixels according to one embodiment of an area A of the display device illustrated in FIG. 1;

FIG. 4 is cross-sectional view taken along line I-I′ of FIG. 3;

FIG. 5 is a perspective view illustrating one example of a first optical pattern of the display device according to an example of the present disclosure;

FIG. 6 illustrates a stacked structure according to one example of a B region of FIG. 4;

FIG. 7 is a plan view illustrating a plurality of pixels according to another embodiment of the area A of the display device illustrated in FIG. 1;

FIG. 8 is cross-sectional view taken along line II-II′ of FIG. 7; and

FIGS. 9A to 9C are diagrams illustrating examples of display devices with a transparent display panel according to one or more embodiments of the present disclosure.

### DETAILED DESCRIPTION OF THE EMBODIMENTS

Hereinafter, the aspects of the present disclosure will be described in detail with reference to the accompanying drawings. The following aspects are provided by way of example so that spirit of the present disclosure can be sufficiently conveyed to those skilled in the art. Thus, the present disclosure can be embodied in different forms and should not be construed as limited to the aspects set forth herein.

A size and a thickness of a device disclosed in the drawings, can be exaggerated for convenience. The scale of the components shown in the drawings are merely an example, and thus the present disclosure is not limited to the illustrated scales. Like reference numerals refer to like elements throughout.

In the following description, when the detailed description of the relevant known technology is determined to unnecessarily obscure the important point of the present disclosure, the detailed description will be omitted.

In a case where ‘comprise,’ ‘have,’ and ‘include’ described in the present disclosure are used, another part can be added. The terms of a singular form can include plural forms unless referred to the contrary.

In describing a positional relationship, for example, when a position relation between two parts is described as ‘on’, ‘over’, ‘under’, and ‘next’, one or more other parts can be disposed between the two parts unless ‘just’ or ‘direct’ is used. The spatially relative terms “below,” “beneath,” “lower,” “above,” “upper,” and the like can be used to facilitate the description of the relationship of one element (or component) to another element (or component) as shown in the drawings. The spatially relative terms should be understood to include different orientations of an element in use or operation in addition to the orientations shown in the drawings. For example, an element described as “below” or “beneath” another element can be placed “above” another element when the elements shown in the drawings are inverted. Thus, the exemplary term “below” can include both below direction and above direction.

It will be understood that, although the terms “first,” “second,”, “A”, “B”, “(a)”, “(b)”, etc. can be used herein to describe various elements of the present disclosure. These terms are only used to distinguish one element from another and the nature, sequence, order, or number of these elements should not be limited by these terms.

In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Features of various aspects of the present disclosure can be partially or totally coupled to or combined with each other, and can be variously inter-operated and driven technically. The aspects of the present disclosure can be carried out independently from each other or can be carried out together with a co-dependent relationship.

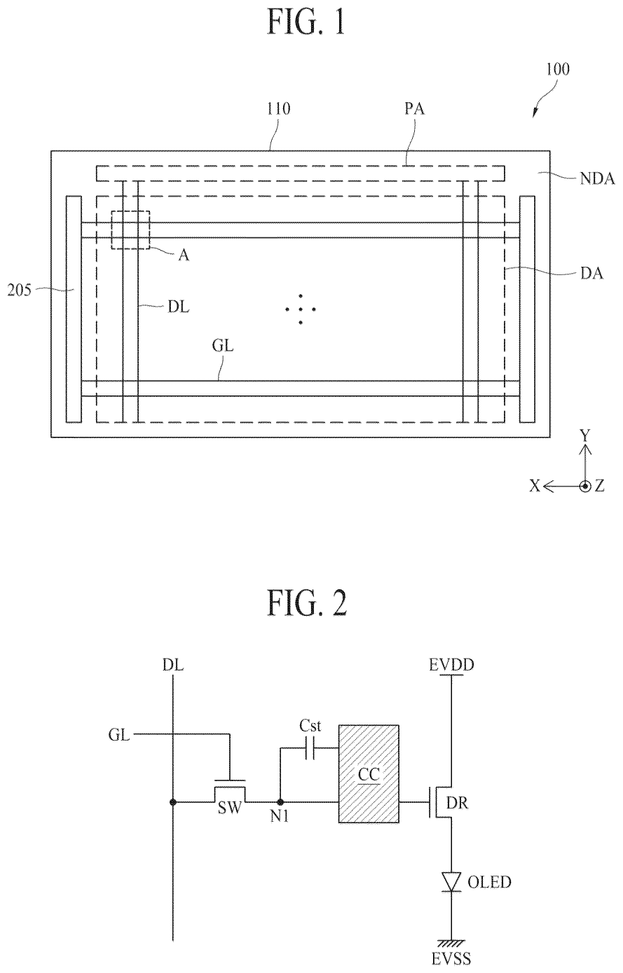

Hereinafter, with reference to the accompanying drawings and embodiments, a display device according to one or more embodiments of the present disclosure is described as follows. FIG. 1 is a illustrates a display apparatus according to an embodiment of the present disclosure, and FIG. 2 is an example of a circuit diagram of a sub-pixel illustrated in FIG. 1.

In FIGS. 1 and 2, an X axis represents a direction parallel to a gate line, a Y axis represents a direction parallel to a data line, and a Z axis represents a height direction of the display device. However, other variations are possible.

An example where a display device 100 according to one or more embodiments of the present disclosure is implemented as an organic light emitting display apparatus will be mainly described, but the display device 100 can be implemented as a liquid crystal display (LCD) apparatus, a plasma display panel (PDP), a quantum dot light emitting display (OLED) apparatus, or an electrophoresis display apparatus.

Referring to FIGS. 1 and 2, the display device 100 according to one or more embodiments of the present disclosure can include a transparent display panel 110. The transparent display panel 110 can be divided into a display area DA and a non-display area NDA outside of (or adjacent to) the display area DA.

The non-display area NDA can be formed in an edge area surrounding the display area DA. In the non-display area NDA, GIP part 205 which is a driving part for driving the pixel and the pad part PA can be disposed.

The display area DA can comprise a plurality of pixels and an image can be displayed through the pixels. Each of the plurality of pixels can include a plurality of sub-pixels.

Referring to FIG. 2, each sub-pixel can include a switching transistor SW, a driving transistor DR, a capacitor Cst, a compensation circuit CC, and an organic light emitting diode OLED.

A first electrode (e.g., a drain electrode) of the switching transistor SW is electrically connected to a data line DL, and a second electrode (e.g., a source electrode) is electrically connected to a first node N1. A gate electrode of the switching transistor SW is electrically connected to a gate line GL. The switching transistor SW supplies a data signal supplied via the data line DL to the first node N1 in response to a scan signal supplied via the gate line GL.

The capacitor Cst is electrically connected to the first node N1 to charge the voltage applied to the first node N1.

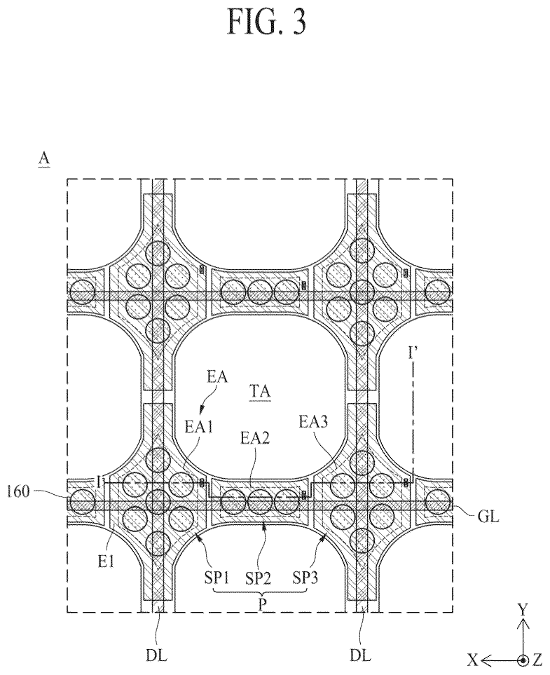

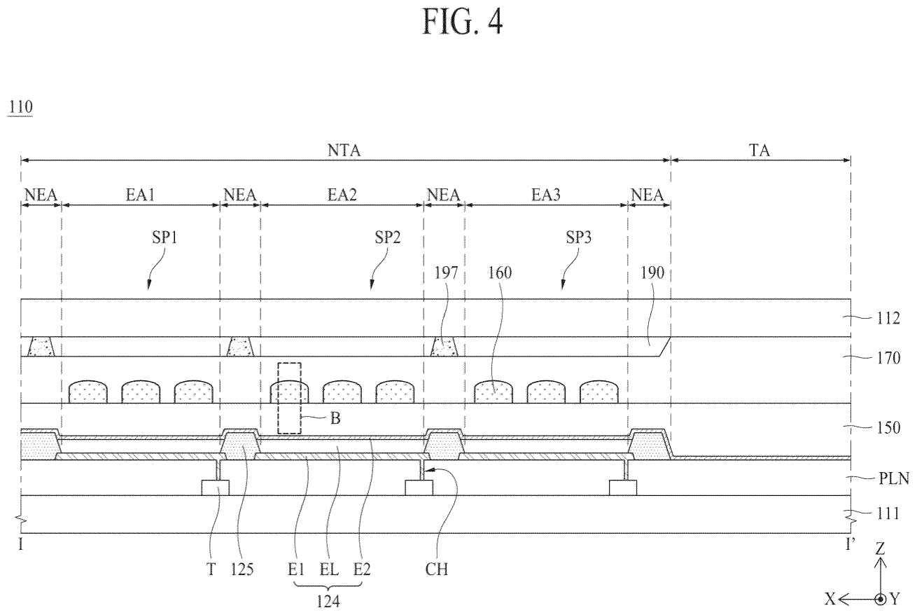

A first electrode (e.g., drain electrode) of the driving transistor DR is applied with a high potential drive voltage EVDD, and a second electrode (e.g., source electrode) is electrically connected to a first electrode (e.g., anode electrode, See E1 shown in FIGS. 3 and 4) of the organic light emitting diode OLED. The driving transistor DR can control the amount of driving current flowing to the organic light emitting diode OLED in response to a voltage applied to a gate electrode.

A semiconductor layer of the switching transistor SW and/or the driving transistor DR can include, but is not limited to, silicon, such as a-Si, poly-Si, or low-temperature poly-Si, or can include an oxide, such as indium-gallium-zinc-oxide IGZO.

The organic light emitting diode OLED outputs light corresponding to the driving current. The organic light emitting diode OLED can output light corresponding to any one of the red color, the green color, and the blue color.

The organic light emitting diode OLED can include an anode electrode, a light emitting layer formed on the anode electrode, and a cathode electrode which applies common voltage. The light emitting layer can be implemented to emit the same color of light per pixel, such as white light, or can be implemented to emit different colors of light per pixel, such as red light, green light, or blue light.

The compensation circuit CC can be disposed in the pixel to compensate for a threshold voltage of the driving transistor DR. The compensation circuit CC can comprise one or more transistors. The compensation circuitry CC can include one or more transistors and capacitors, and can be configured in various ways depending on the compensation method. The pixel comprising the compensation circuit CC can have various structures, such as 3T1C, 4T2C, 5T2C, 6T1C, 6T2C, 7T1C, 7T2C, etc.

FIG. 3 is a plan view showing pixels according to one example of an A region of the display device shown in FIG. 1. FIG. 4 is a cross-sectional view along line I-I′ of FIG. 3.

Referring to FIGS. 3 and 4, the transparent display panel 110 according to one or more example of the present disclosure includes a first substrate 111 and a second substrate 112 facing each other, and a plurality of pixels P capable of transmitting incident light or displaying an image can be arranged in the display area DA.

The display area DA of the transparent display panel 110 includes a transmissive area TA and a non-transmissive area NTA. Each pixel P in the display area DA can include a plurality of sub-pixels SP1, SP2, and SP3 and a transmissive area TA, but other variations are possible.

The non-transmissive area NTA can include a plurality of emission areas EA1, EA2, and EA3 and a non-emission area NEA between the emission areas EA1, EA2, and EA3. The plurality of emission areas EA (EA1, EA2, and EA3) of the non-transmissive area NTA can display an image as areas that emit light through the light emitting device layer 124.

The emission area EA can comprise at least one of a plurality of emission areas EA1, EA2, and EA3 that emit different colors. For example, the plurality of emission areas EA1, EA2, and EA3 can include a red emission area, a green emission area, and a blue emission area, and can further include a white emission area. Alternatively, the plurality of emission areas EA1, EA2, EA3 can comprise at least two of the following emission areas: a red emission area, a green emission area, a blue emission area, a yellow emission area, a magenta emission area, and a cyan emission area. The red emission area is an area that emits red light, the green emission area is an area that emits green light, and the blue emission area is an area that emits blue light. The red emission area, the green emission area, and the blue emission area of the emission areas EA emit a predetermined light and correspond to a non-transmissive area NTA that does not transmit incident light.

Each of the plurality of emission areas EA1, EA2, and EA3 can have a different shape, and each of the plurality of emission areas EA1, EA2, and EA3 can have a polygonal shape.

Each of the plurality of emission areas EA1, EA2, and EA3 can have a different area. The area of each of the plurality emission areas EA1, EA2, and EA3 can be determined by considering the lifespan and light emitting efficiency of the light emitting device layer 124 disposed in each emission area.

For example, when a green light emitting device layer is disposed in the first emission area EA1, a red light emitting device layer is disposed in the second emission area EA2, and a blue light emitting device layer is disposed in the third emission area EA3, the blue light emitting device layer can have the shortest lifespan and the red light emitting device layer can have the longest lifespan in the same area because shorter wavelengths of light have higher energy. Therefore, in order to achieve a uniform lifespan, the area of the second emission area EA2 where the red emitting device layer is disposed can be smaller than the area of the first emission area EA1 where the green emitting device layer is disposed or the area of the third emission area EA3 where the blue emitting device layer is disposed.

On the line (e.g., data line DL) in the row direction or Y direction, the first emission area EA1 and the third emission area EA3 can be alternately arranged. On the line (e.g., gate line GL) in the column direction or X direction, the first emission area EA1 and the third emission area EA3 can be alternately arranged with the second emission area EA2 interposed therebetween.

A first electrode E1 can be disposed in each of the plurality of emission areas EA1, EA2, and EA3.

A plurality of first optical patterns 160 are disposed in the emission area EA. The first optical pattern 160 is arranged to correspond to the emission areas EA1, EA2, and EA3 of the non-transmissive area NTA. The plurality of first optical patterns 160 are disposed in each of the emission areas EA1, EA2, and EA3 to increase the extraction efficiency of the light generated by the light emitting device layer 124 in each of the emission areas EA1, EA2, and EA3. The plurality of first optical patterns 160 can be disposed corresponding to the first electrode E1.

The transmissive area TA is an area that transmits light incident from the outside, allowing viewing of an object or background located on the rear surface of the transparent display panel 110 or the first substrate 111.

FIG. 3 illustrates, but is not limited to, the transmissive area TA elongated in the data line direction (Y-axis direction) and the emission area EA elongated in the gate line direction (X-axis direction). In other words, both the transmissive area TA and the emission area EA can be elongated in the data line direction (Y-axis direction), or both the transmissive area TA and the emission area EA can be elongated in the gate line direction (X-axis direction).

The transmissive area TA can be arranged to have a polygonal shape. The transmissive area TA can be arranged in a polygonal shape including rounds. Since the transmissive area TA of the transparent display panel 110 according to the present disclosure can have a polygonal shape and opposite sides of the adjacent transmissive areas TA may not be parallel to each other, the parallel regularity and periodicity of the transmissive areas TA can be avoided, thereby mitigating the diffraction phenomenon of light.

Specifically, as shown in FIG. 3, the transmissive area TA of the transparent display panel 110 according to the present disclosure can have an octagonal shape including a round or curved shape. When the transmissive area TA has the octagonal shape including the round or curved shape, at least one of the rows or columns of transmissive areas TA disposed adjacent to the direction of a row or column will not have opposing sides disposed parallel to each other, and thus the diffraction phenomenon of light can be mitigated compared to having opposing sides disposed parallel to each other in both the rows and columns.

As shown in FIG. 4, the above described transmissive area TA and non-transmissive area NTA are disposed on a first substrate 111 and a second substrate 112 facing each other and transmit light incident from the outside or display an image by emitting internal light.

The first substrate 111 can be a plastic film, a glass substrate, or a silicon wafer substrate formed using a semiconductor process.

The second substrate 112 can be an encapsulation substrate. The second substrate 112 can be a plastic film, a glass substrate, or an encapsulation film. These first substrate 111 and second substrate 112 can be made of a transparent material.

The first substrate 111 is formed larger than the second substrate 112. This can cause a portion of the first substrate 111 to be exposed and not covered by the second substrate 112.

A circuit element layer T is disposed on the first substrate 111 between the first and second substrates 111 and 112. Circuit elements including various signal lines, thin-film transistor, and capacitor are disposed in the circuit element layer T for each pixel. The signal lines can include gate lines, data lines, driving power lines, common power lines, and reference lines. The thin film transistor can include the switching thin film transistor, the driving thin film transistor, and the sensing thin film transistor.

A planarization film PLN is disposed on the circuit element layer T to planarize the top of the circuit element layer T.

A light emitting device layer 124 is disposed on the planarization film PLN. The light emitting device layer 124 is electrically connected to the circuit element layer T through a contact hole CH below. The light emitting device layer 124 includes a plurality of first electrodes E1, a light emitting layer EL, and a second electrode E2.

The first electrode E1 can include a metal material which is high in reflectivity. For example, the first electrode E1 can be a multi-layer structure such as a stacked structure (titanium/aluminum/titanium (Ti/Al/Ti)) of Al and Ti, a stacked structure (indium tin oxide/Al/indium tin oxide (ITO/Al/ITO)) of Al and ITO, an APC (silver/palladium/copper) alloy, or a stacked structure (ITO/APC/ITO) of an APC alloy and ITO, or can include a single-layer structure including one material or two or more alloy materials selected from among Ag, Al, molybdenum (Mo), gold (Au), magnesium (Mg), calcium (Ca), and barium (Ba).

The light emitting layer EL can be provided on the first electrode E1. The light emitting layer EL can be an organic light emitting layer comprising an organic material. In this case, the light emitting layer EL can include a hole transporting layer, an organic light emitting layer, and an electron transporting layer.

When a voltage is applied to the first electrode E1 and the second electrode E2, holes and electrons are transported to the organic light emitting layer through the hole transporting layer and the electron transporting layer, respectively, and they can be combined with each other in the organic light emitting layer to emit light.

The light emitting layer EL can include a red light emitting layer emitting red light, a green light emitting layer emitting green light, and a blue light emitting layer emitting blue light. The red light emitting layer, the green light emitting layer, and the blue light emitting layer can be patterned on the first electrode E1 by sub-pixels SP1, SP2, and SP3. The red light emitting layer can be patterned in a red pixel, the green light emitting layer can be patterned in a green pixel, and the blue light emitting layer can be patterned in a blue pixel. However, the present disclosure is not limited thereto. Alternatively, the light emitting layer EL can be a white light emitting layer emitting white light. In this case, the light emitting layer EL can be a common layer which is formed in the sub-pixels SP1, SP2, and SP3 in common.

The light emitting layer EL can be provided in a tandem structure of two or more stacks. Each of the stacks can include the hole transporting layer, at least one organic light emitting layer, and the electron transporting layer. A charge generating layer can be provided between the stacks.

The second electrode E2 can be provided over the light emitting layer EL. The second electrode E2 can be provided in the transmissive area TA as well as the non-transmissive area NTA including the emission area EA, but is not limited thereto.

The second electrode E2 can be provided in only the non-transmissive area NTA including the emission area EA and may not be provided in the transmissive area TA, for enhancing a transmittance. The second electrode E2 can be a common layer which is provided in the pixels P in common and applies the same voltage.

The second electrode E2 can include a transparent conductive material (TCO), such as indium tin oxide (ITO) or indium zinc oxide (IZO), or a semi-transmissive conductive material such as magnesium (Mg), silver (Ag), or an alloy of Mg and Ag, which transmit light. When the second electrode E2 is formed of the semi-transmissive conductive material, emission efficiency can be increased by a micro-cavity.

The light emitting device layer 124 can be a pixel array layer in which the pixels P are formed, and the area in which the light emitting device layer 124 is formed can be defined as a display area DA. Sub-pixels SP1, SP2, and SP3 within the display area DA can be partitioned or defined by banks 125.

The bank 125 can be provided at an end of the first electrode E1. Therefore, adjacent first electrodes E1 can be electrically insulated from each other, and emission efficiency can be prevented from being reduced by the concentration of a current on the end of the first electrode E1.

The bank 125 can form an opening portion to expose the planarization film PLN in the transmissive area TA. The bank 125 may not be provided in the transmissive area TA, thereby enhancing a transmittance of the transmissive area TA. The bank 125 can extend from an end of one first electrode E1 to an end of another first electrode E1 disposed adjacent thereto.

The encapsulation layer 150 can be provided over the light emitting device layer 124. The encapsulation layer 150 can prevent penetration of oxygen or water into the light emitting device layer 124. The encapsulation layer 150 can include at least one inorganic film and at least one organic film. The encapsulation layer 150 can be formed in a structure where the inorganic film and the organic film are alternately stacked, but is not limited thereto.

Specifically, as shown in FIG. 6, the encapsulation layer 150 can be formed in a structure where a first inorganic film 151, a second inorganic film 153, a third inorganic film 154, a fourth inorganic film 155, a first organic film 157, and a fifth inorganic film 159 are stacked.

A plurality of first optical patterns 160 are disposed on the encapsulation layer 150. The first optical pattern 160 is arranged to correspond to the emission areas EA1, EA2, and EA3 of the non-transmissive area NTA. The plurality of first optical patterns 160 are disposed in each of the emission areas EA1, EA2, and EA3 to increase the extraction efficiency of the light generated by the light emitting device layer 124 of each of the sub-pixels SP1, SP2, and SP3.

Specifically, when the light generated from the light emitting device layer 124 of each of the sub-pixels SP1, SP2, and SP3 passes the plurality of the first optical patterns 160 through the encapsulation layer 150 toward the second substrate 112, the shape of the first optical pattern 160 allows light to be refracted and concentrated via multiple reflections or diffuse reflections, thereby improving light extraction efficiency.

Accordingly, the display device 100 according to an aspect of the present disclosure can prevent the light emitted from the light emitting device layer 124 from being trapped inside the display device 100 using a plurality of first optical patterns 160 disposed in the emission area EA and improve light extraction, thereby achieving high brightness. Simultaneously, the display device 100 according to the present disclosure can improve the transmittance of the transmissive area TA because the area of the emission area EA can be reduced for the same brightness and the area of the transmissive area TA can be increased.

Thus, the display device 100 according to the present disclosure can extend the lifespan of the display device according to low power, and as the lifespan of the display device increases, the manufacturing process for producing a new display device can be reduced. Thus, the generation of greenhouse gases due to the manufacturing process can be reduced, thereby enabling ESG (Environment/Social/Governance).

The first optical pattern 160 on the encapsulation layer 150 can have a convex shape or a curved portion from the upper surface of the encapsulation layer 150 on the first substrate 111 with respect to the first substrate 111. The first optical patterns 160 can have convex shape including a cylinder shape, or the first optical patterns 160 can have a semi-cylindrical base having a predetermined height and a hemispherical lens shape at the top.

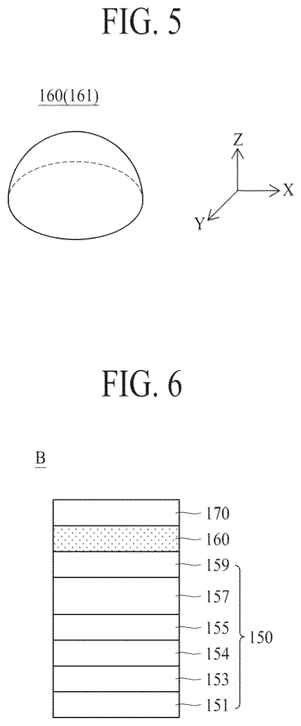

As shown in FIG. 5, the first optical pattern 160 can have a hemispherical lens shape 161. The first optical pattern 160 having a hemispherical lens shape 161 can have a semicircular cross-section in the X and Y directions.

As shown in FIG. 3, a plurality of first optical patterns 160 are disposed in the emission area EA and the plurality of first optical patterns 160 can be spaced apart from each other. In this case, a flat surface can be disposed between each of the first optical patterns 160. The flat surface corresponding to the spaced distance between each of the first optical patterns 160 can be a top surface of the encapsulation layer 150.

The first optical pattern 160 can be a pattern comprising a hemispherical transparent insulating material. The first optical pattern 160 can be made of an organic insulating material. The first optical pattern 160 can be made of an organic insulating material such as photo acrylic.

The first optical pattern 160 can be arranged to correspond to or overlap with a color filter 190.

An optical insulating layer 170 covering the plurality of first optical patterns 160 can be disposed on the encapsulation layer 150.

The optical insulating layer 170 is disposed between the plurality of first optical patterns 160 and the second substrate 112 to mitigate a step cause by the plurality of first optical patterns 160. The first substrate 111 having the optical insulating layer 170 can have a flat top surface over the encapsulation layer 150 because the convex top surface of the plurality of first optical patterns 160 is covered by the optical insulating layer 170. The optical insulating layer 170 does not have a shape that follows the morphology of the curved portion of the first optical patterns 160 and has a flat top surface.

When the upper surface of the first substrate 111 is curved due to the plurality of first optical patterns 160, a haze phenomenon can occur. The optical insulating layer 170 can planarize the upper surface of the plurality of first optical patterns 160 to prevent the haze phenomenon from occurring.

The optical insulating layer 170 disposed on the plurality of first optical patterns 160 can bond or seal the second substrate 112 to the first substrate 111 on which the circuit element layer T, the light emitting device layer 124, and the encapsulation layer 150 are formed.

The optical insulating layer 170 can comprise an organic insulating material. The optical insulating layer 170 can be made of photo acryl, benzocyclobutene BCB, polyimide PI, or polyamide PA.

The optical insulating layer 170 can be an optically clear resin layer OCR or an optically clear adhesive film OCA.

The color filter 190 can further be disposed between the optical insulating layer 170 and the second substrate 112. The color filter 190 can be disposed on one side of the second substrate 112 facing the first substrate 111. The color filter 190 can be disposed to correspond to each of the emission areas EA1, EA2, and EA3 per sub-pixels SP1, SP2, and SP3. The color filter 190 can include a red color filter disposed to correspond to an emission area EA of the red sub-pixel, a green color filter disposed to correspond to an emission area EA of the green sub-pixel, and a blue color filter disposed to correspond to an emission area EA of the blue sub-pixel.

The color filter 190 provided in each of sub-pixels SP1, SP2, and SP3 can be formed to cover the emission area EA. For example, the color filter 190 can have the same area as that of a minimum emission area EA or can have an area which is wider than that of the emission area EA.

The second substrate 112 which is upper substrate can be bonded on the color filter 190. Additionally, without a bonding process to avoid damaging the organic film which is vulnerable to high temperatures, the upper part can be finished in a COE (color-filter on encap) method where a low-temperature color filter process is applied to the substrate.

An insulating layer can further be disposed between the second substrate 112 and the color filter 190. The insulating layer can serve as an adhesive layer, and the insulating layer can comprise an organic or inorganic material.

In the transparent display panel 110 according to one or more embodiments of the present disclosure, the color filter 190 can be formed in the second substrate 112 and light incident from the outside can be prevented from being reflected by the electrodes E1 and E2 inside the transparent display panel 110. For example, the transparent display panel 110 according to one or more embodiments of the present disclosure can decrease an external light reflectance without reducing a transmittance.

A black matrix 197 can be provided between the color filters 190. The black matrix 197 can be disposed in a pattern in the non-emission area NEA per sub-pixels SP1, SP2, and SP3. The black matrix 197 can be arranged to correspond to the bank 125. The black matrix 197 can be disposed to correspond to the non-emission area NEA to prevent light incident from the outside from being reflected by the plurality of lines inside the transparent display panel 110.

The black matrix 197 can be disposed between each of the sub-pixels SP1, SP2, and SP3 in the non-transmissive area NTA. The black matrix 197 can be disposed between the sub-pixels SP1, SP2, and SP3 to prevent the occurrence of a mixed color between adjacent sub-pixels SP1, SP2, and SP3.

The black matrix 197 can include a light-absorbing material, such as a black dye for absorbing all of light of a visible light wavelength band. Further, the black matrix 197 can comprise a stacked structure of adjacent color filters 190. For example, the black matrix 197 can be composed of a stacked structure of the red color filter, the green color filter, and the blue color filter disposed correspondingly to each of the sub-pixels SP1, SP2, and SP3.

The black matrix 197, which comprises a stacked structure of the red color filter, the green color filter, and the blue color filter, can be disposed between the pixels P, which are defined by a collection of at least three sub-pixels SP1, SP2 and SP3.

Although the transparent display panel 110 is illustrated as implemented in a top emission method, it is not limited thereto and can also be implemented in a bottom emission method. In the top emission method, light emitted from the light emitting layer EL is directed toward the second substrate 112, so that the circuit element layer T can be spaced widely below the bank 125 and the first electrode E1. Therefore, the top emission method has the advantage of a larger design area for the circuit element layer T compared to the bottom emission method.

As described above, each of the pixels P of the display device 100 comprising the transparent display panel 110 according to one or more embodiments of the present disclosure includes the transmissive area TA that passes incident light almost intact and the emission area EA that has a first optical pattern 160 and emits light. As a result, the transparent display panel 110 of the display device 100 according to one or more embodiments of the present disclosure can improve the transmittance of the transmissive areas TA through which an object or background located on the rear surface can be seen, while at the same time improving the light extraction efficiency of the light emitted from the emission area EA.

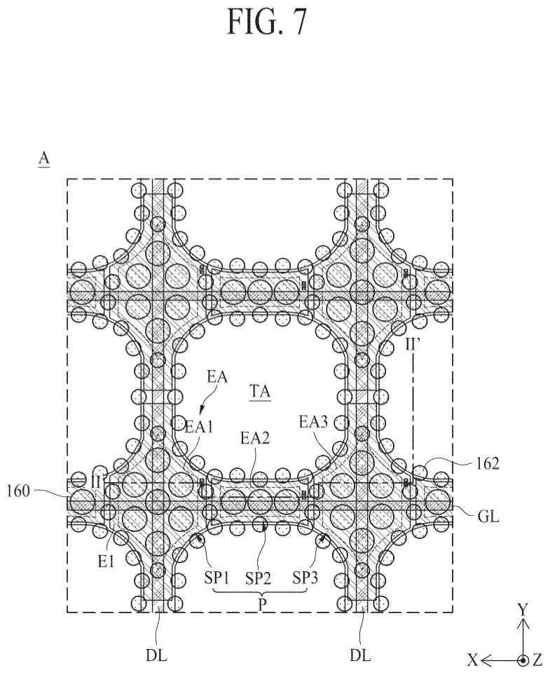

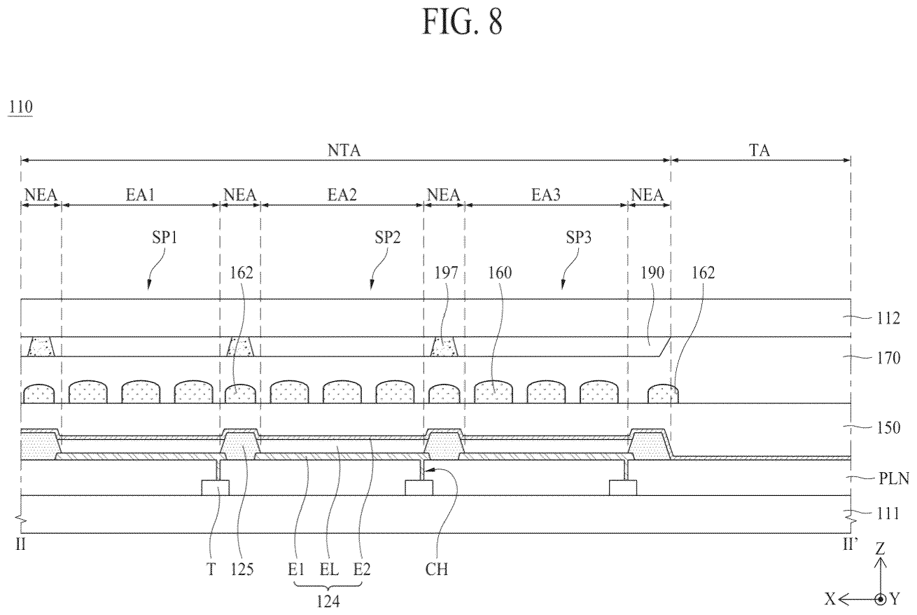

FIG. 7 illustrates a plurality of pixels P according to another embodiment in an area A in a display apparatus (or display device) 100 according to another embodiment of the present description, and FIG. 8 is a cross-sectional view along line II-II′ of FIG. 7. Hereinafter, the description omits the redundant description of the like reference numerals described above or can be provided briefly.

As shown in FIGS. 7 and 8, the display device 100 according to another embodiment of the present disclosure includes a transparent display panel 110 having a transmissive area TA and a non-transmissive area NTA in the display area DA, formed by bonding a first substrate 111 and a second substrate 112.

The transparent display panel 110 can transmit external light or display an image with internal emitted light through a transmissive area TA and a non-transmissive area NTA disposed on the first substrate 111 and the second substrate 112 facing each other.

The non-transmissive area NTA comprises a plurality of emission areas EA1, EA2, and EA3 defined by banks (125, see FIG. 8). The first optical pattern 160 is disposed on each of the emission areas EA1, EA2, and EA3. A second optical pattern 162 overlapping at least partially with the transmissive area TA is disposed at the border of the transmissive area TA.

The plurality of emission areas EA1, EA2, and EA3 can display the image and can be areas that emit light using the light emitting device layer 124.

The emission area EA can comprise at least one of a plurality of emission areas EA1, EA2, and EA3 that emit different colors. For example, the plurality of emission areas can include a red emission area, a green emission area, and a blue emission area, and can further include a white emission area. Alternatively, the plurality of emission areas EA1, EA2, and EA3 can include at least two of the among a red emission area, a green emission area, a blue emission area, a yellow emission area, a magenta emission area, and a cyan emission area. A red emission area is an area that emits red light, a green emission area is an area that emits green light, and a blue emission area is an area that emits blue light. The red emission area, the green emission area, and the blue emission area of the emission areas EA emit a predetermined light and correspond to the non-transmissive area NTA that does not transmit incident light.

The plurality of first optical patterns 160 can be disposed in the emission area EA. The first optical patterns 160 are arranged to correspond to the emission areas EA1, EA2, and EA3 of the non-transmissive area NTA. The plurality of first optical patterns 160 can be disposed in each of the emission areas EA1, EA2, and EA3 to increase the extraction efficiency of the light generated by the light emitting device layer 124 in each of the emission areas EA1, EA2, and EA3. The plurality of first optical patterns 160 can be disposed corresponding to the first electrode E1.

Each of the plurality of emission areas EA1, EA2, and EA3 can have a different shape, and each of the plurality of emission areas EA1, EA2, and EA3 can have a polygonal shape.

Each of the emission areas EA1, EA2, and EA3 can have a different area. The area of each of the emission areas EA1, EA2, and EA3 can be determined by considering the lifespan and light emitting efficiency of the light emitting device layer 124 disposed in each of the emission areas EA1, EA2, and EA3.

For example, when a green light emitting device layer is disposed in the first emission area EA1, a red light emitting device layer is disposed in the second emission area EA2, and a blue light emitting device layer is disposed in the third emission area EA3, the blue light emitting device layer can have the shortest lifespan and the red light emitting device layer can have the longest lifespan in the same area because shorter wavelengths of light have higher energy. Therefore, in order to achieve a uniform lifespan, the area of the second emission area EA2 where the red emitting device layer is disposed can be smaller than the area of the first emission area EA1 where the green emitting device layer is disposed or the area of the third emission area EA3 where the blue emitting device layer is disposed.

In this case, the number of the first optical patterns 160 can be determined differently for each emission area EA. For example, as in the previous example, when a green light emitting device layer is disposed in the first emission area EA1, a red light emitting device layer is disposed in the second emission area EA2, and a blue light emitting device layer is disposed in the third emission area EA3, the number of the first optical patterns 160 disposed in the third emission area EA3 is greater than the number of the first optical patterns 160 disposed in the first emission area EA1, and the number of the first optical patterns 160 disposed in the first emission area EA1 can be greater than the number of the first optical patterns 160 disposed in the second emission area EA2. The number of the first optical patterns 160 disposed in the third emission area EA3 can be greater than the number of the first optical patterns 160 disposed in the second emission area EA2.

On the lines in the row direction or Y direction (e.g., data line DL), the first light emission area EA1 and the third emission area EA3 can be arranged alternately. On the lines in the column direction or X direction (e.g., gate line GL), the first emission area EA1 and the third emission area EA3 can be arranged alternately with the second emission area EA2 in therebetween.

In detail, on the line in a predetermined column direction or X direction (e.g., gate line GL), a green light emitting device layer can be disposed in the first emission area EA1, a red light emitting device layer can be disposed in the second emission area EA2, and a blue light emitting device layer can be disposed in the third emission area EA3. On the subsequent line in the column direction or X direction (e.g., gate line GL), a blue light emitting device layer can be disposed in the first emission area EA1, a red light emitting device layer can be disposed in the second emission area EA2, and a green light emitting device layer can be disposed in the third emission area EA3.

In this case, the number of first optical patterns 160 can be determined differently for each emission area EA, taking into account the lifespan of the light emitting device layer 124, etc.

For example, it is assumed that, on the line in a predetermined column direction or X direction, a green light emitting device layer is disposed in the first emission area EA1, a red light emitting device layer is disposed in the second emission area EA2, and a blue light emitting device layer is disposed in the third emission area EA3. It is further assumed that, on the subsequent line in a predetermined column direction or X direction, a blue light emitting device layer is disposed in the first emission area EA1, a red light emitting device layer is disposed in the second emission area EA2, and a green light emitting device layer is disposed in the third emission area EA3. In this, the number of the first optical patterns 160 disposed in the emission area EA in which the blue light emitting device layer is disposed is greater than the number of the first optical patterns 160 disposed in the emission area EA in which the green light emitting device layer is disposed, and the number of the first optical patterns 160 disposed in the emission area EA in which the green light emitting device layer is disposed can be greater than the number of the first optical patterns 160 disposed in the emission area EA in which the red light emitting device layer is disposed.

The first optical patterns 160 can have a convex shape or a curved portion from the top surface of the encapsulation layer 150 on the first substrate 111 with respect to the first substrate 111. The first optical patterns 160 can be convex shape including a cylindrical shape, or the first optical patterns 160 can have a semi-cylindrical base having a predetermined height and a hemispherical lens shape at the top.

As shown in FIG. 5, the first optical pattern 160 can have a hemispherical lens shape 161, the first optical pattern 160 having a hemispherical lens shape 161 can have a semicircular cross-section in the X and Y directions.

The transmissive area TA is an area that transmits light incident from outside, an object or background located on the rear surface of the transparent display panel 110 or the first substrate 111 can be seen.

The transmissive areas TA can be arranged to have a polygonal shape. The transmissive area TA of the transparent display panel 110 according to other embodiments of the present disclosure can comprise an embossed pattern or a concavo-convex pattern, as shown in FIG. 7. The embossed pattern or concavo-convex pattern is formed on a border line of the transmissive area TA. The border line of the transmissive area TA can be an octagonal shape, further comprising an embossed pattern or a concavo-convex pattern.

The embossed pattern or concavo-convex pattern can be formed by an edge or shape of a plurality of second optical patterns 162 disposed on the border of the transmissive area TA. The embossed pattern or concavo-convex pattern can be a pattern corresponding to an edge or shape of the plurality of second optical patterns 162 disposed on the border of the transmissive area TA.

The embossed pattern or concavo-convex pattern can be described as having a plurality of patterns in which the border lines of the transmissive area TA protrudes towards the transmissive area TA and/or the non-transmissive area NTA when viewed in plan view. Here, the border lines of the transmissive area TA protruding towards the transmissive area TA can comprise an embossed pattern or a concavo-convex pattern comprising a round or curved shape.

One example of a border of the transmissive area TA can be an edge or end of the transmissive area TA.

As shown in FIG. 8, a plurality of second optical patterns 162 are disposed on the encapsulation layer 150 and at least a portion of the second optical pattern 162 can overlap the border of the transmissive area TA. By arranging a plurality of second optical patterns 162 that overlap at least partially the transmissive area TA at the border of the transmissive area TA, the diffraction phenomenon can be reduced and the haze phenomenon can be improved.

Specifically, by arranging the plurality of second optical patterns 162 that overlap at least partially the transmissive area TA at the border of the transmissive area TA, the border of the transmissive area TA can have an embossed shape or a concavo-convex shape as shown in FIG. 7. Generally, the transmissive area TA serves as a slit, and diffraction phenomenon in which the direction of light is curved can occur in the slit. The diffraction phenomenon can cause haze, and the border of the transmissive area TA of the display device 100 according to the present disclosure can have the embossed shape or concavo-convex shape to avoid periodic repetition and regularity of the lines on the border of the transmissive area TA. Furthermore, the display device 100 according to the present disclosure can reduce the parallel arrangement between the border lines of the transmissive areas TA adjacent to each other, thereby reducing the occurrence of diffraction phenomenon and improving haze. Thus, the display device 100 with the transparent display panel 110 according to the present disclosure can improve the image quality clarity or visibility of the display device and can improve readability.

When disposed such that at least a portion of the second optical pattern 162 overlaps with the transmissive area TA at the border of the transmissive area TA, the second optical pattern 162 can be disposed in a zigzag arrangement or irregular arrangement. Specifically, a predetermined second optical pattern 162 disposed at the border of the transmissive area TA can be disposed to overlap the transmissive area TA more or less than a subsequent second optical pattern 162 disposed at the border of the transmissive area TA.

When the second optical patterns 162 are disposed in a zigzag arrangement such that the area overlapping with the transmissive area TA is different, the transmissive areas TA disposed adjacent to each other may not have opposite sides disposed parallel to each other, and the periodicity, repeatability, parallelism, etc. of the border line of the transmissive area TA can be further destroyed or further avoided, thereby further reducing the occurrence of diffraction phenomenon and further improving haze. Therefore, the display device 100 with the transparent display panel 110 according to the present disclosure can prevent the border between the emission area EA and the transmissive area TA from being perceived by a user, thereby improving readability and enhancing visibility.

The plurality of second optical patterns 162 can be disposed such that at least a portion of the second optical pattern 162 overlaps both the non-transmissive area NTA and the transmissive area TA. The plurality of second optical patterns 162 can be disposed such that the second optical pattern 162 overlaps at least partially with the border of the emission area EA.

The second optical pattern 162 can be disposed to have a different shape from the first optical pattern 160. The second optical pattern 162 can have a convex shape or a curved portion from the top surface of the encapsulation layer 150 on the first substrate 111 with respect to the first substrate 111. The second optical pattern 162 can be a convex shape including a cylindrical shape, or the second optical pattern 162 can be a pattern having a semi-cylindrical base having a predetermined height and a hemispherical lens shape at the top.

As shown in FIG. 5, the second optical pattern 162 can have the same shape as the first optical pattern 160, and can have a hemispherical lens shape 161. The second optical pattern 162 having a hemispherical lens shape 161 can have a semicircular cross-section in the X-direction and Y-direction.

The height of the second optical pattern 162, which is arranged to overlap at least partially the border of the transmissive area TA, can be lower than the height of the first optical pattern 160. When the height of the second optical pattern 162 is lower than the height of the first optical pattern 160, the occurrence of a sharp step at the border of the emission area EA or the border between the emission area EA and the transmissive area TA can be prevented or the step can be alleviated.

Specifically, when the second optical pattern 162 has a smaller thickness or lower height than the first optical pattern 160 between the emission area EA and the transmissive area TA, the deviation of the step at the border of the emission area EA can be reduced. As the deviation of the step is reduced, the display device 100 according to the present disclosure can prevent or reduce distortion of light or image as light generated in the emission area EA passes through the plurality of layers towards the second substrate 112 due to the step.

Accordingly, the display device 100 according to aspects of the present disclosure can control the height or width of the second optical pattern 162 disposed at the border of the emission area EA to improve the image quality clarity of the display device 100.

The horizontal width of the second optical pattern 162 can be smaller than the horizontal width of the first optical pattern 160. Alternatively, when the second optical pattern 162 has a hemispherical lens shape, the diameter of the second optical pattern 162 can be smaller than the diameter of the first optical pattern 160.

The second optical pattern 162 can be disposed to overlap with the bank 125, which is disposed between the non-emission area NEA or emission area EA and the transmissive area TA.

The second optical pattern 162 can be disposed to overlap the black matrix 197.

The second optical pattern 162, which is disposed to overlap with at least a portion of the transmissive area TA, can be disposed in the same layer and made of the same material as the first optical pattern 160, which is disposed in the emission area EA.

The second optical pattern 162 can be a pattern comprising a hemispherical transparent insulating material. The second optical pattern 162 can be made of an organic insulating material. The second optical pattern 162 can comprise an organic insulating material of the photoacrylic type.

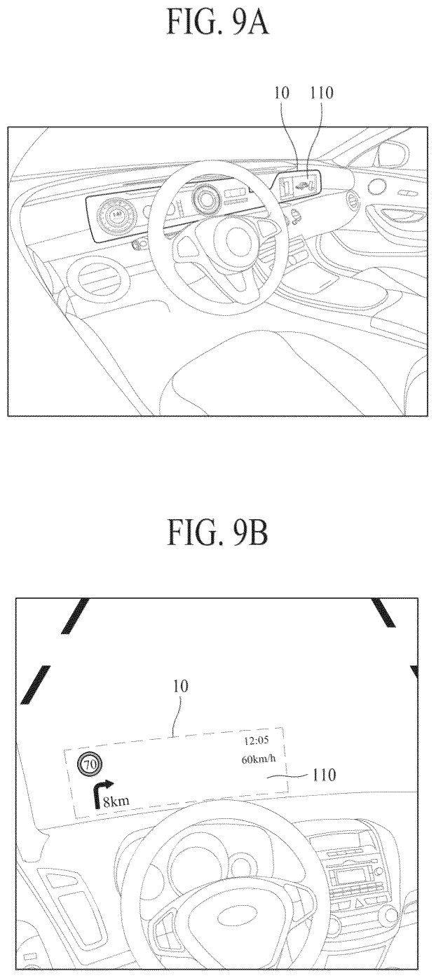

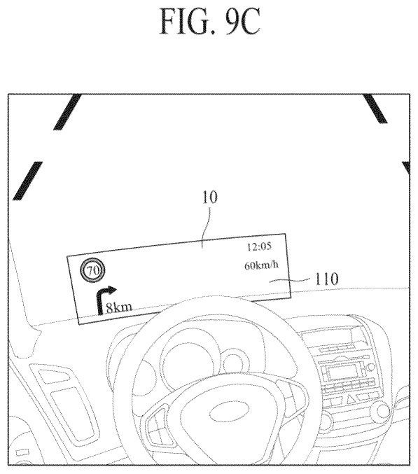

The display device 100 comprising the transparent display panel 110 as described above can further comprises a tempered glass 10 disposed on the transparent display panel 110 for application to mobility such as a vehicle. For example, as illustrated in FIGS. 9B and 9C, transparent display panel 110 applied to mobility can be disposed on the center fascia or dashboard of the vehicle with the tempered glass 10, or can be disposed integral with the windscreen behind the steering wheel of the vehicle, or can be disposed in a form such a heads-up display HUD disposed between the steering wheel and the windscreen of the vehicle, to allow the driver to view necessary information for driving the vehicle or general information while keeping the driver's head up. A mobility type display device with the transparent display panel 110 according to the present disclosure can display an image corresponding to a speedometer, a tachometer, a fuel gauge, an odometer, a coolant thermometer, a turn signal indicator, a low fuel warning light, an alternator warning light, a signal lamp, a clock, or the like. In addition, the mobility type display device with the transparent display panel 110 according to the present disclosure can also display a navigation screen for displaying a map or road to a destination of the map.

In the present disclosure, the extraction efficiency of the light emitted from the light emitting device layer inside the display device can be improved by disposing a plurality of optical patterns in the emission area, or the transmittance can be improved by enlarging the area of the transmissive area for the same light extraction efficiency.

Moreover, in the present disclosure, it is possible to achieve high transmittance and high brightness due to light extraction.

Moreover, in the present disclosure, the plurality of optical patterns can be disposed at the border of the transmissive area, at least partially overlapping with the border of the transmissive area. Accordingly, in the present disclosure, a regularity and a periodicity at the border of the transmissive area can be avoided to minimize the occurrence of diffraction phenomenon of light, thereby preventing diffraction patterns from occurring or reducing haze values, thereby improving the image quality clarity or visibility of the display device and improving readability.

Moreover, in the present disclosure, by disposing in zigzag arrangement or irregularly the plurality of the optical patterns overlapping the border of the transmissive area, the border between the emission area and transmissive area can be prevented from being perceived by the user, thereby improving readability and visibility.

Moreover, in the present disclosure, the optical patterns disposed in the emission area and the optical patterns disposed at the border of the transmissive area can be controlled to have different heights or widths, such that distortion of the image through the emission area can be prevented, thereby improving image quality clarity.

Moreover, in the present disclosure, high efficiency and high brightness can be achieved by improving the light gathering efficiency through the plurality of optical patterns. Accordingly, in the present disclosure, the lifespan of the display device can be extended and it is possible to enable low-power operation by reducing power consumption.

Thus, when implementing the display device, the present disclosure can reduce the manufacturing process for producing new display devices as the lifespan of the display device increases, thereby reducing the generation of greenhouse gases due to the manufacturing process, thereby implementing ESG (Environment/Social/Governance).

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A transparent display device, comprising:
a display area including a transmissive area and a non-transmissive area;
a plurality of emission areas disposed in the non-transmissive area; and
a plurality of first optical patterns disposed in each of the plurality of emission areas.

2. The transparent display device of claim 1, wherein the transmissive area has a polygonal shape including a round portion.

3. The transparent display device of claim 1, wherein the transmissive area has an octagonal shape including a round or curved portion.

4. The transparent display device of claim 1, wherein the plurality of emission areas comprise:
a first emission area in which a green light emitting device layer is disposed;
a second emission area in which a red light emitting device layer is disposed; and
a third emission area in which a blue light emitting device layer is disposed, and
wherein the number of the plurality of first optical patterns disposed in the third emission area is greater than the number of the plurality of first optical patterns disposed in the second emission area, or the number of the plurality of first optical patterns disposed in the first emission area is greater than the number of the plurality of first optical patterns disposed in the second emission area.

5. The transparent display device of claim 1, wherein the plurality of first optical patterns are spaced apart from one another.

6. The transparent display device of claim 1, wherein the plurality of emission areas comprise a light emitting device layer and an encapsulation layer disposed on the light emitting device layer,
wherein the light emitting device layer is formed by stacking a first electrode, a light emitting layer, and a second electrode, and
wherein the plurality of first optical patterns are disposed on the encapsulation layer.

7. The transparent display device of claim 1, wherein each of the plurality of first optical patterns has a hemispherical lens shape.

8. The transparent display device of claim 1, wherein each of the plurality of first optical patterns has a semi-cylindrical base having a predetermined height and a hemispherical lens shape at a top portion thereof.

9. The transparent display device of claim 1, further comprising a plurality of second optical patterns disposed at a border of the transmissive area.

10. The transparent display device of claim 9, wherein the plurality of second optical patterns are disposed in a zigzag arrangement or an irregular arrangement at the border of the transmissive area, and at least partly overlap the transmissive area.

11. The transparent display device of claim 9, wherein a predetermined second optical pattern among the plurality of second optical patterns is disposed to overlap at least partially with the border of the transmissive area, and a subsequent second optical pattern is disposed to overlap with the transmissive area more or less than the predetermined second optical pattern.

12. The transparent display device of claim 9, wherein the plurality of second optical patterns are disposed to overlap at least partially with the border of the transmissive area, and
the border of the transmissive area has an embossed pattern or a concavo-convex pattern corresponding to a border or shape of the plurality of second optical patterns.

13. The transparent display device of claim 9, wherein the plurality of second optical patterns are disposed on a same layer as the plurality of first optical patterns and are made of a same material as the plurality of first optical patterns.

14. The transparent display device of claim 9, wherein each of the plurality of second optical patterns has a hemispherical lens shape.

15. The transparent display device of claim 9, wherein a height of the plurality of second optical patterns is lower than a height of the first optical patterns.

16. The transparent display device of claim 9, wherein each of the plurality of second optical patterns is disposed to overlap at least partially with both the transmissive area and the non-transmissive area.

17. The transparent display device of claim 9, further comprising an encapsulation layer disposed on the transmissive area and the non-transmissive area,
wherein the plurality of second optical patterns are disposed on the encapsulation layer.

18. The transparent display device of claim 17, further comprising an optical insulating layer configured to cover the plurality of first optical patterns and the plurality of second optical patterns disposed on the encapsulation layer.

19. The transparent display device of claim 1, wherein a border of the transmissive area has an embossed pattern or a concavo-convex pattern.

20. The transparent display device of claim 1, further comprising an optical insulating layer disposed on the plurality of first optical patterns to mitigate a step caused by the plurality of first optical patterns, wherein the optical insulating layer has a flat top surface.

21. A display device, comprising:
a transparent display panel having a transmissive area and a non-transmissive area in a display area of a first substrate and a second substrate, the first and second substrates facing each other; and
a tempered glass disposed on the transparent display panel,
wherein a plurality of emission areas and a first optical pattern disposed on the plurality of emission areas are disposed in the non-transmissive area, and
wherein a plurality of second optical patterns are disposed between the transmissive area and the non-transmissive area.
